(19) United States
(12) Patent Application Publication
(10) Pub. No.: US 2026/0334066 A1
(43) Pub. Date: Oct. 22, 2026

(54) DISPLAY DEVICE AND ELECTRONIC DEVICE

(71) Applicant: Samsung Display Co., LTD., Yongin-si (KR)

(72) Inventors: SEUNG-WOON SHIN, Yongin-si (KR); KYOUNGSOO KIM, Yongin-si (KR); JONGDEUK MOON, Yongin-si (KR); HO LEE, Yongin-si (KR); WOON-ROK JANG, Yongin-si (KR)

(21) Appl. No.: 19/468,546

(22) Filed: Feb. 3, 2026

(30) Foreign Application Priority Data
Feb. 5, 2025 (KR) 10-2025-0014334

(51) Int. Cl. H10K 59/80; H10K 102/00

(52) U.S. Cl. CPC H10K 59/8794; H10K 59/873; H10K 59/8791; H10K 2102/351

(57) ABSTRACT

A display device includes a first substrate including one surface and another surface opposite to the one surface, a display layer positioned on the one surface of the first substrate which displays an image, an encapsulating layer covering the display layer, a second substrate positioned on the encapsulating layer, and at least one heat-dissipating film arranged between the first substrate and the second substrate and including aluminum nitride (AlN).

This application claims priority to Korean Patent Application No. 10-2025-0014334, filed on Feb. 5, 2025, and all the benefits accruing therefrom under 35 U.S.C. §119, the content of which in its entirety is herein incorporated by reference.

### BACKGROUND

### 1. FIELD

The disclosure relates to a display device and an electronic device including the display device.

### 2. DESCRIPTION OF THE RELATED ART

Display devices may display an image using a light-emitting element. Display devices are applied to various electronic devices such as smartphones, digital cameras, laptop computers, navigation systems, televisions, and the like, and are being developed in various forms. Technology development is actively underway to improve heat dissipation performance for heat generated when light-emitting elements of display devices emit light.

### SUMMARY

The disclosure provides a display device with improved heat dissipation performance and an electronic device including the display device.

According to an aspect of the disclosure, a display device includes a first substrate including one surface and another surface opposite to the one surface, a display layer positioned on the one surface of the first substrate and which displays an image, an encapsulating layer covering the display layer, a second substrate positioned on the encapsulating layer, and at least one heat-dissipating film arranged between the first substrate and the second substrate and including aluminum nitride (AlN).

In some embodiments, the first heat-dissipating film may be positioned between the one surface of the first substrate and the display layer.

In some embodiments, the heat-dissipating film may be formed directly on the one surface of the first substrate.

In some embodiments, the encapsulating layer may include a thin-film encapsulating layer, and the heat-dissipating film may be positioned between the thin-film encapsulating layer and the second substrate.

In some embodiments, the encapsulating layer may include at least a filler, and the display device may further include an optical functional layer which is positioned on the filler, scatters external light, and includes one surface and another surface opposite to the one surface and facing the encapsulating layer, and the heat-dissipating film may be positioned between the filler and the other surface of the optical functional layer.

In some embodiments, the heat-dissipating film may be formed directly on the other surface of the optical functional layer.

In some embodiments, the at least one heat-dissipating film may include a first heat-dissipating film and a second heat-dissipating film, the first heat-dissipating may be positioned between the one surface of the first substrate and the display layer, and the second heat-dissipating film may be positioned between the encapsulating layer and the second substrate.

In some embodiments, the display device may further include an optical functional layer which is positioned on the encapsulating layer, scatters external light, and includes one surface and another surface opposite to the one surface and facing the encapsulating layer, and the at least one heat-dissipating film may include a first heat-dissipating film and a second heat-dissipating film, the first heat-dissipating film may be formed directly on the one surface of the first substrate, and the second heat-dissipating film may be formed directly on the other surface of the optical functional layer.

In some embodiments, the first heat-dissipating film and the second heat-dissipating film may have a same thickness.

In some embodiments, the first heat-dissipating film and the second heat-dissipating film may have different respective thicknesses.

In some embodiments, a thickness of the heat-dissipating film may be more than 0 micrometer, but not more than 1 micrometer.

In some embodiments, a thermal conductivity of the heat-dissipating film in a planar direction may be at least 55 W/mK, but not more than 200 W/mK.

In some embodiments, a light transmissivity of the heat-dissipating film may be at least 70%, but not more than 95% at a wavelength of 400 nanometers to 800 nanometers.

In some embodiments, the display layer may include at least one unit pixel, and the at least one unit pixel may include a plurality of light-emitting areas which emit light and at least one transparent window which transmits external light.

In some embodiments, the at least one transparent window may be arranged in common across the plurality of light-emitting areas.

In some embodiments, at least one insulating layer of the display layer corresponding to the at least one transparent window may be removed.

According to another aspect of the disclosure, an electronic device includes a first substrate including one surface and another surface opposite to the one surface, a display layer positioned on the one surface of the first substrate and including at least one unit pixel including a plurality of sub-pixels, an encapsulating layer covering the display layer, a second substrate positioned on the encapsulating layer, a controller which applies a signal to pixel circuits respectively included in the plurality of sub-pixels, a power module which applies power to the controller, and at least one heat-dissipating film arranged between the first substrate and the second substrate and including aluminum nitride (AlN), wherein the at least one heat-dissipating film has a thickness being more than 0 micrometer, but not more than 1 micrometer.

In some embodiments, the heat-dissipating film may be formed directly on the one surface of the first substrate.

In some embodiments, the heat-dissipating film may be formed between the encapsulating layer and the second substrate.

In some embodiments, the electronic device may further include an optical functional layer which is positioned on the encapsulating layer, scatters external light, and includes one surface and another surface opposite to the one surface and facing the encapsulating layer, in which the at least one heat-dissipating film includes a first heat-dissipating film and a second heat-dissipating film, the first heat-dissipating film is formed directly on the one surface of the first substrate, and the second heat-dissipating film is formed directly on the other surface of the optical functional layer.

In some embodiments, each unit pixel may include at least one transparent window which transmits external light.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a schematic perspective view of an electronic device according to an embodiment;

FIG. 2 is a perspective view illustrating a display device included in an electronic device according to an embodiment;

FIGS. 3A-3C are cross-sectional views of a display panel according to embodiments, cut along line III-III;

FIG. 4 is a plan view illustrating a display layer of a display device according to an embodiment;

FIGS. 5A and 5B are plan views illustrating enlarged examples of V in FIG. 4;

FIG. 6 is a cross-sectional view cut along line VI-VI in FIG. 5A;

FIG. 7 is an explanatory view illustrating a portion of a display panel according to another embodiment of the disclosure;

FIG. 8 is a plan view illustrating a pixel structure of a transparent display panel;

FIG. 9 is a cross-sectional view cut along line IX-IX in FIG. 8;

FIGS. 10A-10C are explanatory views illustrating a portion of a display panel according to another embodiment of the disclosure;

FIG. 11 is a block diagram of an electronic device according to an embodiment; and

FIG. 12 show schematic diagrams of an electronic device according to various embodiments.

### DETAILED DESCRIPTION

The disclosure may have various modifications thereto and various embodiments, and thus particular embodiments will be illustrated in the drawings and described in detail in a detailed description. Effects and features of the disclosure, and methods for achieving them will become clear with reference to the embodiments described later in detail together with the drawings. However, the disclosure is not limited to the embodiments disclosed below and may be implemented in various forms.

In the following embodiments, the terms such as first, second, and the like, have been used to distinguish one component from other components, rather than limiting.

In the following embodiments, singular forms include plural forms unless apparently indicated otherwise contextually.

In the following embodiments, the terms "include", "have", or the like, are intended to mean that there are features, or components, described herein, but do not preclude the possibility of adding one or more other features or components.

In the following embodiments, when a portion, such as a film, a region, a component, etc., is present on or above another portion, this case may include not only a case where it is directly on the other portion, but also a case where another film, region, component, etc., is arranged between the portion and the other portion.

In the following embodiments, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. For example, as the size and thickness of each component illustrated in the drawings are arbitrarily illustrated for convenience of description, the disclosure is not necessarily limited to the illustration.

In the following embodiments, when various components such as layers, films, regions, plates, etc., are “on” other components, this may include not only a case where they are “right on” the other components, but also a case where other components are interposed between them. In the drawings, the size of components may be exaggerated or reduced for convenience of description. For example, as the size and thickness of each component illustrated in the drawings are arbitrarily illustrated for convenience of description, the disclosure is not necessarily limited to the illustration.

In the following embodiments, a direction orthogonal to or crossing a first direction DR1 may be defined as a second direction DR2. A third direction DR3 may be defined as a direction substantially perpendicularly crossing a plane defined by the first direction DR1 and the second direction DR2.

In the following embodiments, “up” or “down” may be defined with respect to the third direction DR3.

In the following embodiments, a scan driver, a scan signal, a scan control signal, a scan line, and a scan control line may also be referred to as a gate driver, a gate signal, a gate control signal, a gate line, and a gate control line, respectively.

In the following embodiments, in case that “about” is used in connection with a numerical value, it is intended to include a tolerance of ±10% around the numerical value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Hereinafter, embodiments of the disclosure will be described in detail with reference to the attached drawings, and in the description with reference to the drawings, identical or corresponding components are given the same reference numerals and redundant descriptions thereof will be omitted.

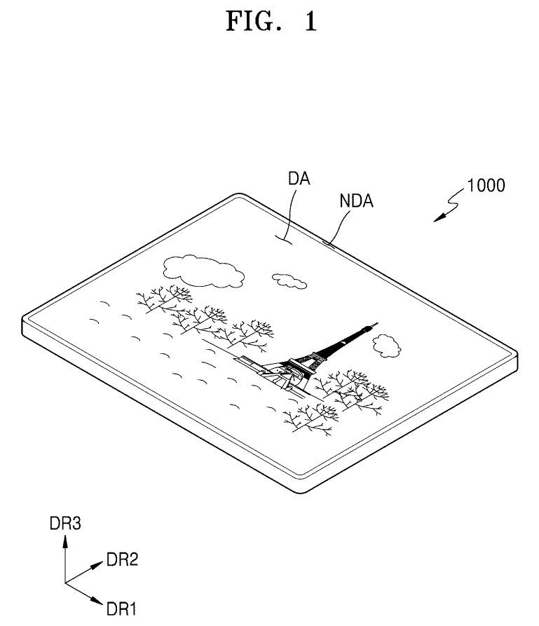

FIG. 1 is a schematic perspective view of an electronic device 1000 according to an embodiment.

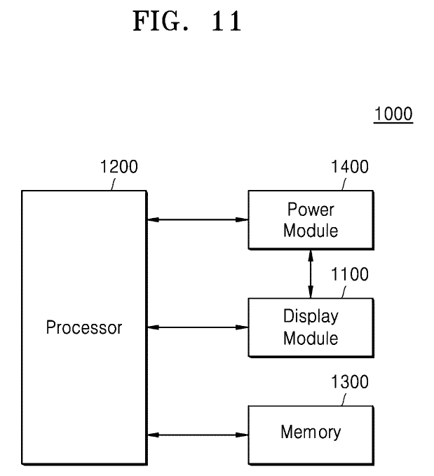

Referring to FIG. 1, the electronic device 1000 may refer to any electronic device that provides a display screen. For example, a television, a laptop computer, a monitor, a billboard, an Internet of Things (IoT), a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation system, a game console, a digital camera, a camcorder, etc., which provides a display screen, may be included in the electronic device 1000. Hereinbelow, a smartphone is taken as an example of the electronic device 1000, but the disclosure is not limited thereto. Additional details of the electronic device 1000 may be further described in FIG. 11.

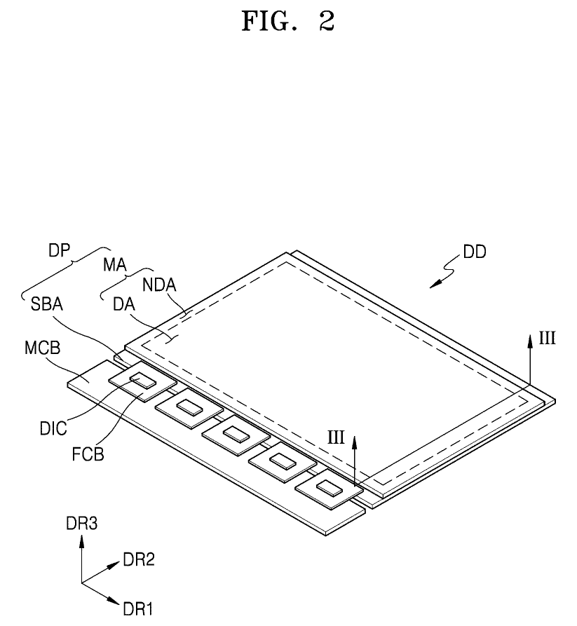

The electronic device 1000 may include a display device DD of FIG. 2 providing the display screen as one module. Examples of the display device DD may include inorganic light-emitting diode display devices, organic light-emitting display devices, quantum dot light-emitting display devices, plasma display devices, field emission display devices, etc. Hereinbelow, an organic light-emitting diode is used as an example of a display device, but the disclosure is not limited thereto, and other display devices may be used as long as the same technical idea is applicable thereto.

The shape of the electronic device 1000 may be modified in various ways. For example, the electronic device 1000 may have a shape such as a long-width rectangle, a long-length rectangle, a square, a rectangle with rounded corners (vertices), other polygons, a circle, etc. The shape of a display area DA of the electronic device 1000 may also be similar to the overall shape of the electronic device 1000. In FIG. 1, the electronic device 1000 having a long-length rectangular shape in the first direction DR1 is illustrated.

The electronic device 1000 may include the display area DA and a non-display area NDA. The display area DA may be an area where a screen may be displayed, and the non-display area NDA may be an area where a screen is not displayed. The display area DA may also be referred to as an active area, and the non-display area NDA may also be referred to as an inactive area. The display area DA may generally occupy the center of the electronic device 1000.

FIG. 2 is a perspective view illustrating the display device DD included in the electronic device 1000 according to an embodiment.

Referring to FIG. 2, the electronic device 1000 according to an embodiment may include the display device DD. The display device DD may provide a screen to be displayed on the electronic device 1000. The display device DD may have a flat shape similar to the electronic device 1000. For example, the display device DD may have a shape similar to a rectangle having a long side in a first direction DR1 and a short side in the second direction DR2. A corner where the long side in the first direction DR1 and the short side in the second direction DR2 meet may be formed roundly to have a curvature, but the disclosure is not limited thereto and the corner may also be formed at a right angle. The flat shape of the display device DD is not limited to a quadrangle, and may be formed similarly to other polygons, circles, or ovals.

The display device DD may include a display panel DP, a display driving unit DIC, and a circuit board MCB.

The display panel DP may include a main area MA and a sub area SBA.

The main area MA may include the display area DA including sub-pixels presenting an image, and the non-display area NDA arranged around the display area DA. The display area DA may emit light from a plurality of light-emitting areas or a plurality of opening areas. For example, the display panel DP may include a pixel circuit including switching elements, a pixel-defining film defining a light-emitting area or an opening area, and a self-light-emitting element.

For example, the self-light-emitting element may include, but is not limited to, at least one of an organic light-emitting diode (OLED) including an organic light-emitting layer, a quantum dot LED including a quantum dot light-emitting layer, an inorganic LED including an inorganic semiconductor, and a micro light-emitting diode (micro LED).

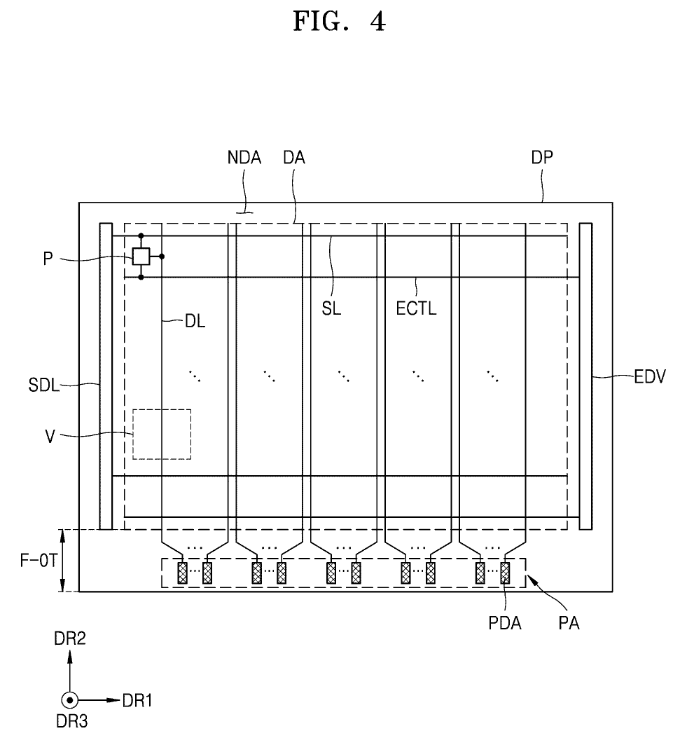

The non-display area NDA may be outside the display area DA. The non-display area NDA may be defined as an edge area of the main area MA of the display panel DP. The non-display area NDA may include a scan driver SDV of FIG. 4 that supplies scan signals to scan lines, and fan- out lines F-OT of FIG. 4 that connect the display driving unit DIC to the display area DA.

A sub-area SBA may be an area extending from a side of the main area MA. The sub-area SBA may include the display driving unit DIC and a pad portion (not illustrated) connected to the circuit board MCB. In another embodiment, the sub-area SBA may be omitted, and the display driving unit DIC and the pad portion may be arranged in the non-display area NDA.

The display driving unit DIC may output signals and voltages for driving the display panel DP. The display driving unit DIC may supply data voltages to data lines. For example, the display driving unit DIC may include a data driver that may supply data voltages to data lines. The data voltage may be supplied to a plurality of sub-pixels P of FIG. 4 to control the brightness of the plurality of sub-pixels P. The display driving unit DIC may supply a power voltage to a power line and supply a scan control signal to the scan driver SDV of FIG. 4. The display driving unit DIC may be formed as an integrated circuit (IC) and electrically connected to the display panel DP by a flexible circuit film (FCB), but the disclosure is not limited thereto, and may be mounted on the display panel DP in a chip on glass (COG) manner, a chip on plastic (COP) manner, or an ultrasonic bonding manner.

The circuit board MCB may be electrically connected to the pad portion of the display panel DP in connection to the FCBs. The circuit board MCB may include a plurality of driving elements. The plurality of driving elements may include circuitry for driving the display panel DP. Lead lines of the circuit board MCB may be electrically connected to the pad portion of the display panel DP. The circuit board MCB may be a printed circuit board.

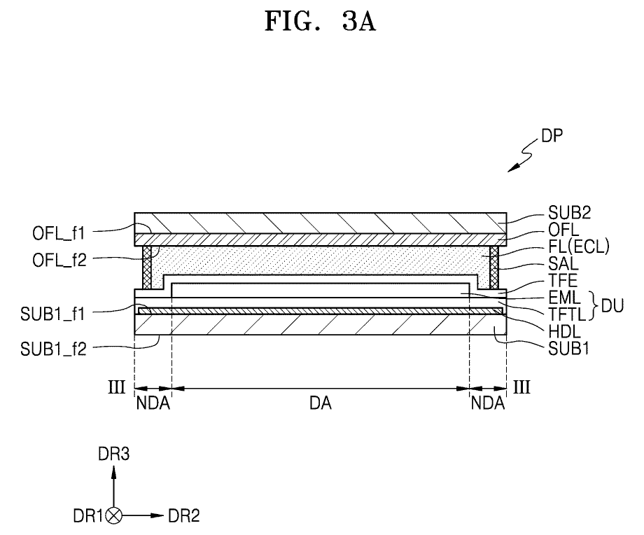

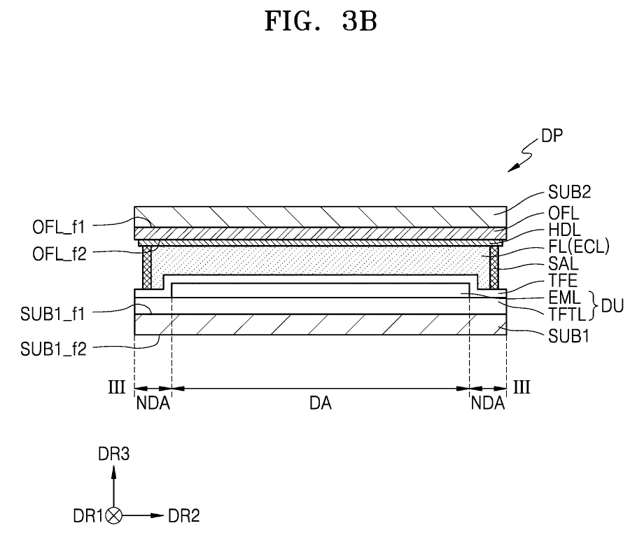

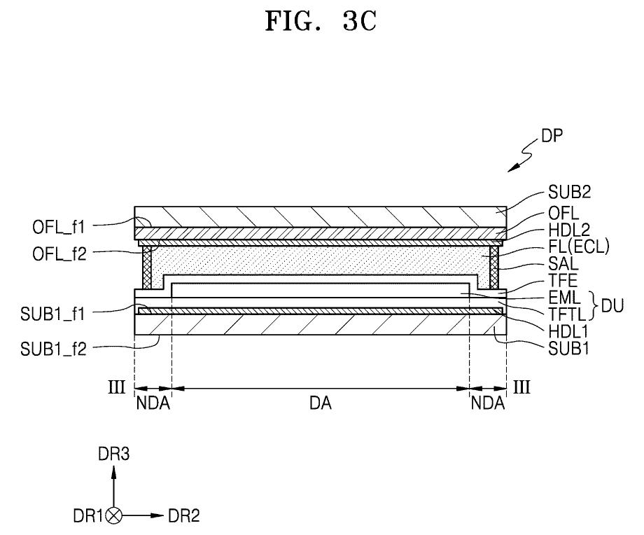

FIGS. 3A-3C are cross-sectional views of the display panel DP according to embodiments, cut along line III-III.

Referring to FIGS. 3A-3C, the display panel DP may include a first substrate SUB1 in the third direction DR3, a display layer DU arranged on a surface of the first substrate SUB1 and displaying an image, a filler FL covering the display layer DU, an optical functional layer OFL arranged on the filler FL, and a second substrate SUB2 arranged on a surface of the optical functional layer OFL. Each layer may include a surface and another surface, and in the third direction DR3, the surface may mean a layer located on an upper side, and the other surface may mean a layer located on a lower side. In the third direction DR3, a thin film transistor layer TFTL, a light-emitting element layer EML, and a thin-film encapsulating layer TFE may be provided on the first substrate SUB1 in the third direction DR3. The filler FL may be referred to as an encapsulating layer ECL. However, without limitation, a combination of the filler FL and the thin-film encapsulating layer TFE may also be referred to as the encapsulating layer ECL.

The first substrate SUB1 may be a base substrate or a base member. For example, the first substrate SUB1 may include, but is not limited to, a glass material. In another embodiment, the first substrate SUB1 may include a polymer resin such as polyimide (PI) or a metal material. Hereinbelow, an example will be given in which the first substrate SUB1 is formed of a glass material.

The thin film transistor layer TFTL may be arranged on the first substrate SUB1. The thin film transistor layer TFTL may include a plurality of thin film transistors that constitute a pixel circuitry of sub-pixels. The thin film transistor layer TFTL may further include scan lines, data lines, power lines, scan control lines, fan out lines connecting the display driving unit DIC to the data lines, and lead lines connecting the display driving unit DIC to the pad portion. Each of thin film transistors may include a semiconductor region, a source electrode, a drain electrode, and a gate electrode.

The thin film transistor layer TFTL may be arranged in the display area DA, the non-display area NDA, and the sub-area SBA. Thin film transistors, scan lines, data lines, and power lines of respective sub-pixels of the thin film transistor layer TFTL may be arranged in the display area DA. Scan control lines and fan out lines of the thin film transistor layer TFTL may be arranged in the non-display area NDA. Lead lines of the thin film transistor layer TFTL may be arranged in the sub-area SBA.

The light-emitting element layer EML may be arranged on the thin film transistor layer TFTL. The light-emitting element layer EML may include a plurality of light-emitting elements that emit light, including a pixel electrode, a common electrode, and a light-emitting layer, and a pixel-defining film that defines light-emitting regions. The plurality of light-emitting elements of the light-emitting element layer EML may be arranged in the display area DA.

In an embodiment, the light-emitting layer may be an organic light-emitting layer including an organic material. The light-emitting layer may include a hole transporting layer, an organic light-emitting layer, and an electron transporting layer. In an example in which the pixel electrode receives a voltage through the thin film transistor of the thin film transistor layer TFTL and the common electrode receives a cathode voltage, holes and electrons may move to the organic light-emitting layer through the hole transport layer and the electron transport layer, respectively, and emit light in combination with each other in the organic light-emitting layer.

In other embodiments, the light-emitting element may include a quantum dot light-emitting diode including a quantum dot light-emitting layer, an inorganic light-emitting diode including an inorganic semiconductor, or a micro light-emitting diode.

The thin-film encapsulating layer TFE may be arranged on the thin film transistor layer TFTL to cover the light-emitting element layer EML. The thin-film encapsulating layer TFE may include a stacked structure of at least one inorganic layer and at least one organic layer. The thin-film encapsulating layer TFE may protect the light-emitting element layer EML from moisture, oxygen, and external foreign substances.

The second substrate SUB2 may be arranged on the first substrate SUB1 and may face the first substrate SUB1. Similar to the first substrate SUB1, the second substrate SUB2 may include, but is not limited to, a glass material.

The optical functional layer OFL may be arranged under the second substrate SUB2. When viewed on a plane, the optical functional layer OFL may overlap the display area DA. A portion of the optical functional layer OFL may also overlap the non-display area NDA. The optical functional layer OFL may prevent color distortion by blocking reflection of external light and scattering the external light. The optical functional layer OFL may be a low-reflection layer. Although not illustrated, the optical functional layer (OFL) may further include a color filter layer that prevents reflection of external light and/or a light conversion layer that converts light emitted from the display area DA.

A sealant SAL may be arranged between the first substrate SUB1 and the second substrate SUB2. The first substrate SUB1 and the second substrate SUB2 may be bonded to each other by the sealant SAL. The sealant SAL may be arranged between the thin-film encapsulating layer TFE and the optical functional layer OFL and may overlap the non-display area NDA. The sealant SAL may contain a ultraviolet-curable material.

The filler FL may be arranged between the thin-film encapsulating layer TFE and the optical functional layer OFL and overlap the display area DA. The filler FL may extend toward the non-display area NDA and contact the sealant SAL. The filler FL may be arranged in a space between the first substrate SUB1 and the second substrate SUB2, and the incorporation of the filler FL may improve physical adhesion between the first substrate SUB1 and the second substrate SUB2 and protect a display element against impact applied from the outside of the display panel DP. The filler FL may include a thermosetting material of urethane series, silicone series, epoxy series, and acrylic series. For example, as the urethane series, urethane acrylate, etc., may be used. As the acrylic-series products, butylacrylate, ethylhexylacrylate, etc., may be used.

According to an embodiment of the disclosure, the display panel DP may include at least one heat-dissipating film HDL arranged between the first substrate SUB1 and the second substrate SUB2. The heat-dissipating film HDL may be located inside the display panel DP. Thus, the thickness and weight of the display panel DP may be reduced compared to a conventional heat sink located outside the display panel DP. As the heat-dissipating film HDL is located inside the display panel DP and thus is closer to heat generating sources, such as light-emitting elements, electrodes, and wires, heat may be dissipated quickly and evenly. As the heat-dissipating film HDL is integrated inside the display panel DP, the display panel DP may be implemented without a separate assembly of an external heat sink, thereby simplifying a manufacturing process.

The heat-dissipating film HDL may include or may be formed of a material having high thermal conductivity. As the heat-dissipating film HDL includes or is formed of a material with high thermal conductivity, the heat dissipation performance may be improved, thereby preventing momentary afterimages from being worsened during a peak box test. The peak box test refers to testing heat generation, a momentary afterimage level, and brightness performance after illuminating a part of the display area DA of the display panel DP (e.g., 3%, 10%, etc., of an area of the entire display area DA) at high brightness (e.g., 4000 nit, 2500 nit, etc.) for a certain period of time (e.g., 20 seconds, etc.) and then turning it (the display panel DP) off. Herein, a peak box refers to a region of the display area DA illuminated at high brightness. When current for illuminating a part of the display area at high brightness in a peak box test, the temperature of the display panel DP rises, causing problems with the reliability of the display device (DD). As the momentary afterimages are worsened by heat generation and thus the peak box test at high brightness is impossible, image quality competitiveness may be weakened. However, by improving the heat dissipation performance of the display device DD through the heat-dissipating film HDL, the momentary afterimage problem may be mitigated and the peak box test at high brightness may be possible.

The heat-dissipating film HDL may include or be formed of an insulating material. Thus, as the heat-dissipating film HDL does not form electrodes or wires and capacitor components arranged between the first substrate SUB1 and the second substrate SUB2, signal interference and power consumption problems do not occur, and further heat generation does not occur.

To satisfy the foregoing conditions, the heat-dissipating film HDL may include at least aluminum nitride (AlN). The heat-dissipating film HDL may be formed of aluminum nitride.

The thickness of the heat-dissipating film HDL may be more than about 0 micrometer, but not more than about 1 micrometer. As the heat-dissipating film HDL formed of aluminum nitride within a corresponding thickness range has high light transmissivity, the heat-dissipating film HDL may have a high heat dissipation effect without a decrease in light transmissivity, even for a transparent display device including a transparent window through which external light passes. By applying the heat-dissipating film HDL to the display panel DP, heat dissipation may be improved even for transparent display devices for which conventional opaque graphite or metal heat sinks may not be applicable.

The thermal conductivity of the heat-dissipating film HDL in a planar direction may be at least about 55 W/mK, but not more than 200 W/mK. In a thermal conductivity in the corresponding value range, the heat-dissipating film HDL formed of aluminum nitride may have excellent thermal compatibility with the first substrate SUB1 or the optical functional layer OFL on which the heat-dissipating film HDL is arranged, thereby minimizing cracks or delamination that may occur due to thermal expansion mismatch.

The light transmissivity of the heat-dissipating film HDL may be at least about 70%, but not more than about 95% at a wavelength of about 400 nanometers to about 800 nanometers. The light-emitting element layer EML may primarily emit light having a wavelength of about 400 nanometers to 800 nanometers. Thus, in case that the display device DD is a transparent display device including a transparent window transmitting external light, as the heat-dissipating film HDL transmits light of about 70 % to about 95 % in the corresponding wavelength range, the external light transmission of the display device DD is not hindered despite at least one heat-dissipating film HDL being arranged between the first substrate SUB1 and the second substrate SUB2.

In FIGS. 3A-3C, to help understanding, a surface SUB1-f1 and the other surface SUB1-f2 of the first substrate SUB1, and a surface OFL-f1 and another surface OFL-f2 of the optical functional layer OFL are illustrated. Referring to FIG. 3A, the heat-dissipating film HDL may be located between the surface SUB1-f1 of the first substrate SUB1 and the display layer DU. The heat-dissipating film HDL may be arranged between the surface SUB1-f1 of the first substrate SUB1 and the thin film transistor layer TFTL. The heat-dissipating film HDL may be directly deposited on the surface SUB1-f1 of the first substrate SUB1. The heat-dissipating film HDL may be deposited on the first substrate SUB1 through a process such as sputtering, chemical vapor deposition, molecular beam epitaxy, coating, etc.

Referring to FIG. 3B, the heat-dissipating film HDL may be located between the filler FL and the other surface OFL-f2 of the optical functional layer OFL. The heat-dissipating film HDL may be directly deposited on the other surface OFL-f2 of the optical functional layer OFL. The heat-dissipating film HDL may be deposited on the first substrate SUB1 through performing a process such as sputtering, chemical vapor deposition, molecular beam epitaxy, coating, etc., on the other surface OFL-f2 of the optical functional layer OFL. The heat-dissipating film HDL may be formed on the other surface OFL-f2 of the optical functional layer OFL rather than the other surface of the second substrate SUB2, thereby preventing scattering and reflection of external light from being hindered.

Referring to FIG. 3C, the display panel DP may include a plurality of heat-dissipating films HDL. The plurality of heat-dissipating films HDL may include at least a first heat-dissipating film HDL1 and a second heat-dissipating film HDL2. The first heat-dissipating film HDL1 may be located between the surface SUB1-f1 of the first substrate SUB1 and the display layer DU, similarly to the embodiment of FIG. 3A. The first heat-dissipating film HDL1 may be arranged between the surface SUB1-f1 of the first substrate SUB1 and the thin film transistor layer TFTL. The first heat-dissipating film HDL1 may be directly deposited on the surface SUB1-f1 of the first substrate SUB1. The second heat-dissipating film HDL2 may be positioned between the filler FL and the other surface OFL-f2 of the optical functional layer OFL, similarly to the embodiment of FIG. 3B. The second heat-dissipating film HDL2 may be directly deposited on the other surface OFL-f2 of the optical functional layer OFL. The first heat-dissipating film HDL1 and the second heat-dissipating film HDL2 may be deposited on the other surface OFL-f2 of the optical functional layer OFL through a process such as sputtering, chemical vapor deposition, molecular beam epitaxy, coating, etc.

In an embodiment, the thicknesses of the first heat-dissipating film HDL1 and the second heat-dissipating film HDL2 may be equal to each other. In another embodiment, the thicknesses of the first heat-dissipating film HDL1 and the second heat-dissipating film HDL2 may be different from each other. For example, the thickness of the first heat-dissipating film HDL1 may be greater than the thickness of the second heat-dissipating film HDL2. Thus, heat generated from the display layer DU on the first substrate SUB1 may be discharged more efficiently, and the problem of light transmissivity being affected by the first heat-dissipating film HDL1 in front light emission to emit light toward the second substrate SUB2 may be prevented.

FIG. 4 is a plan view illustrating the display panel DP of a display device according to an embodiment.

Referring to FIG. 4, the display panel DP may include the display area DA and the non-display area NDA.

The display area DA may be arranged in the center of the display panel DP. The display area DA may include a plurality of sub-pixels P, a plurality of scan lines SL, a plurality of data lines DL, a plurality of light-emission control lines ECTL, and a plurality of power lines (not illustrated). Each of the plurality of sub-pixels PX may be defined as a minimum unit that emits light.

The plurality of scan lines SL may supply scan signals received from the scan driver SDV to the plurality of sub-pixels P. The plurality of scan lines SL may extend in the first direction DR1 and may be spaced apart from each other in the second direction DR2 intersecting the first direction DR1.

The plurality of data lines DL may supply a data voltage received from the display driving unit DIC or a data driver in the display driving unit DIC to the plurality of sub-pixels P. The plurality of data lines DL may extend in the second direction DR2 and may be spaced apart from each other in the first direction DR1.

The plurality of light-emission control lines ECTL may supply a light-emission control signal received from the light-emission control driver EDV to the plurality of sub-pixels P. The plurality of light-emission control lines ECTL may extend in the first direction DR1 and may be spaced apart from each other in the second direction DR2 intersecting the first direction DR1.

The plurality of power lines (not illustrated) may supply a power voltage received from the display driving unit DIC to the plurality of sub-pixels P. The power voltage may be at least one of a driving voltage (or a first voltage ELVDD), an initialization voltage, a reference voltage, and a low-potential voltage (or a second voltage ELVSS). The plurality of power lines may extend in the second direction DR2 and be spaced apart from each other in the first direction DR1, but are not limited thereto and may be implemented in various forms.

The non-display area NDA may surround the display area DA. The scan driver SDV, the fan out line FOL, the light-emission control deriver EDV, etc., may be arranged in the non-display area NDA. The scan driver SDV may generate a plurality of scan signals based on a scan control signal and sequentially supply the plurality of scan signals to the plurality of scan lines SL in a set order. The light-emission control driver EDV may generate a plurality of light-emission control signals and sequentially supply the plurality of light-emission control signals to the plurality of light-emission control lines ECTL in a set order.

The sub-area SBA may include the fan-out lines F-OT and the pad area PA.

The fan-out lines F-OT may receive signals and voltages for driving the display panel DP from the display driving unit DIC of FIG. 2 electrically connected to the flexible circuit films FCB of FIG. 2 and transmit them to the display panel DP.

The pad area PA may include a plurality of display pad portions PAD. The plurality of display pad portions PAD may be connected to a graphics system through the circuit board MCB of FIG. 2. The plurality of display pad portions PAD may be connected to the circuit board MCB of FIG. 2 through the flexible circuit films FCB of FIG. 2 to receive digital video data and supply the digital video data to the display driving unit DIC of FIG. 2.

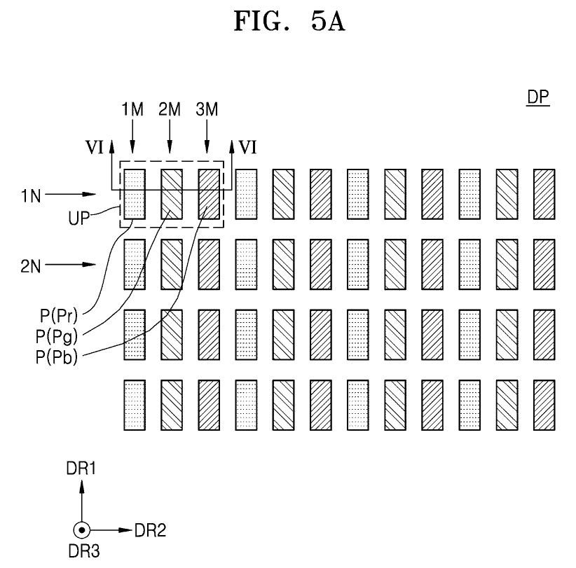

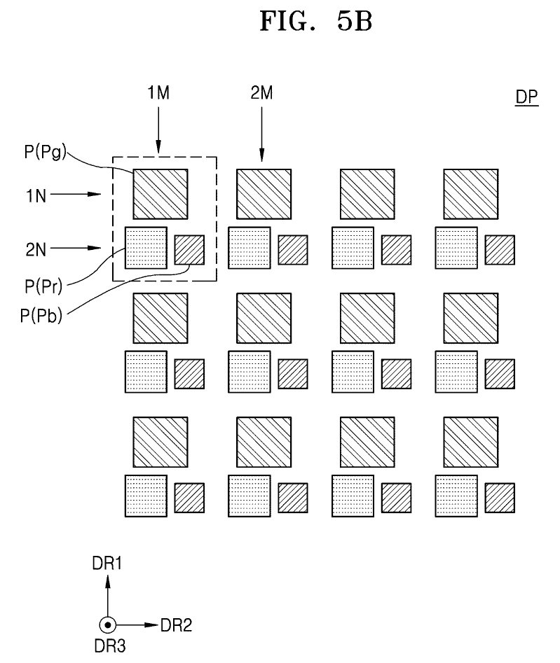

FIGS. 5A and 5B are plan views illustrating enlarged examples of V in FIG. 4.

A unit pixel UP may include at least two sub-pixels P aligned in a row direction or a column direction. The unit pixel UP may be the smallest unit of pixel constituting an image. The unit pixel UP may include one or more sub-pixels P. For example, referring to FIGS. 5A and 5B, the unit pixel UP may include a red sub-pixel Pr, a green sub-pixel Pg, and a blue sub-pixel Pb.

Referring to FIG. 5A, the red sub-pixels Pr, the green sub-pixel Pg, and the blue sub-pixels Pb may be arranged in a first row 1N alternately in the second direction DR2. In a second row 2N, the red sub-pixel Pr, the green sub-pixel Pg, and blue sub-pixel Pb may also be arranged alternately in the second direction DR2. This arrangement of sub-pixels may be repeated up to a selected number of rows.

The red sub-pixels Pr may be arranged continuously in a first column 1M in the first direction DR1, the green sub-pixel Pg may be arranged continuously in a second column 2M adjacent to the first column 1M in the first direction DR1, and the blue sub-pixel Pb may be arranged continuously in a third column 3M adjacent to the second column 2M in the first direction DR1. This arrangement of sub-pixels may be repeated up to a selected number of columns.

The red sub-pixel Pr, the green sub-pixel Pg, and the blue sub-pixel Pb may have the same size. Such arrangement of the sub-pixels may be referred to as a stripe structure.

Referring to FIG. 5B, in the first row 1N, the green sub-pixels Pg may be spaced apart by a selected space in the second direction DR2. In the second row 2N adjacent to the first row 1N, the red sub-pixel Pr and the blue sub-pixel Pb may be arranged alternately in the second direction DR2. The space between the green sub-pixels Pg arranged in the first row 1N may be less than the space between the red sub-pixel Pr and the blue sub-pixel Pb (between the red sub-pixels Pr and the blue sub-pixels Pb) arranged in the second row 2N. This arrangement of sub-pixels may be repeated up to a selected number of rows.

In the first column 1M, the green sub-pixel Pg and the red sub-pixels (Pr) and/or the blue sub-pixels (Pb) may be arranged alternately in the first direction DR1. This arrangement of sub-pixels may be repeated up to a selected number of rows. In the second column 2M adjacent to the first column 1M, the green sub-pixel Pg and the red sub-pixels (Pr) and/or the blue sub-pixels (Pb) may be arranged alternately in the first direction DR1. This arrangement of sub-pixels may be repeated up to a selected number of rows.

By connecting the centers of the green sub-pixel Pg, the blue sub-pixel Pb, and the red sub-pixel Pr that constitute one unit pixel UP, the shape of a triangle may be formed. Such arrangement of the sub-pixels may be referred to as a triangular structure.

The red sub-pixel Pr, the green sub-pixel Pg, and the blue sub-pixel Pb may have different sizes. For example, the size of the green sub-pixel Pg may be greater than the size of the red sub-pixel Pr, and the size of the red sub-pixel Pr may be greater than the size of the blue sub-pixel Pb.

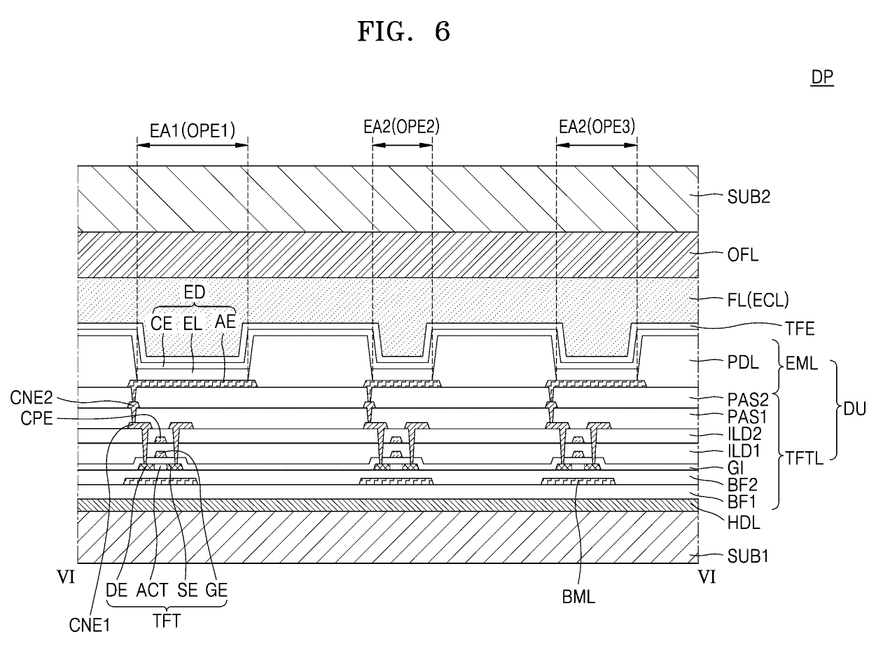

FIG. 6 is a cross-sectional view cut along line VI-VI in FIG. 5A.

Referring to FIG. 6, the display panel DP may include the first substrate SUB1, the heat-dissipating film HDL, the display layer DU, the thin-film encapsulating layer TFE, the filler FL, the optical functional layer OFL, and the second substrate SUB2. The display layer DU may include the thin film transistor layer TFTL and the light-emitting element layer EML.

The heat-dissipating film HDL may be arranged on a surface of the first substrate SUB1. Although FIG. 6 illustrates the embodiment of FIG. 3A, the disclosure is not limited thereto. The heat-dissipating film HDL may be arranged on the other surface of the optical functional layer OFL as described in FIG. 3B, or may be arranged on both a surface of the first substrate SUB1 and the other surface of the optical functional layer OFL as described in FIG. 3C. As the heat-dissipating film HDL is the same as described herein, a redundant description will be omitted.

On the heat-dissipating film HDL, the light-emitting element layer EML that displays the screen and the thin film transistor layer TFTL that drives the light-emitting element layer EML may be arranged.

The thin film transistor layer TFTL may include a first buffer layer BF1, a lower metal layer BML, a second buffer layer BF2, a thin film transistor TFT, a gate insulation layer GI, a first interlayer insulation layer ILD1, a capacitor electrode CPE, a second interlayer insulation layer ILD2, a first connection electrode CNE1, a first passivation layer PAS1, a second connection electrode CNE2, and a second passivation layer PAS2.

The first buffer layer BF1 may include an inorganic film capable of preventing the penetration of air or moisture. For example, the first buffer layer BF1 may include a plurality of inorganic films laminated alternately.

The lower metal layer BML may be arranged on the first buffer layer BF1. The lower metal layer BML may be arranged such that the lower metal layer BML overlaps the thin film transistor TFT, and the lower metal layer BML may block and prevent light from reaching a semiconductor layer ACT, thereby preventing light-induced current. For example, the lower metal layer BML may be formed as a single layer or a plurality of layers formed of one or more of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing the penetration of air or moisture. For example, the second buffer layer BF2 may include a plurality of inorganic films laminated alternately.

The thin film transistor TFT may be formed in a sub-pixel on the second buffer layer BF2. The thin film transistor TFT may be arranged on the second buffer layer BF2 and may form a pixel circuit of sub-pixels. For example, the thin film transistor TFT may be a driving transistor or a switching transistor in the pixel circuit. The thin film transistor TFT may include a semiconductor layer ACT, a source electrode SE, a drain electrode DE, and a gate electrode GE.

The semiconductor layer ACT may be arranged on the second buffer layer BF2. The semiconductor layer ACT may overlap the lower metal layer BML and the gate electrode GE in the thickness direction, and may be insulated from the gate electrode GE by the gate insulation layer GI. The semiconductor layer ACT may be formed of an oxide semiconductor with high light transmissivity. For example, the semiconductor layer ACT may be formed of one or more oxide semiconductor materials selected from an indium gallium zinc oxide (IGZO), a zinc oxide (ZnO), an indium oxide (In₂O₃), or a tin oxide (SnO₂).

The gate electrode GE may be arranged on the gate insulation layer GI. The gate electrode GE may overlap the semiconductor layer ACT, with the gate insulation layer GI interposed between the gate electrode GE and the semiconductor layer ACT.

The gate insulation layer GI may be arranged on the semiconductor layer ACT. For example, the gate insulation layer GI may cover the semiconductor layer ACT and the second buffer layer BF2, and may insulate the semiconductor layer ACT from the gate electrode GE. The gate insulation layer GI may include a contact hole through which the first connection electrode CNE1 passes.

The first interlayer insulation layer ILD1 may cover the gate electrode GE and the gate insulation layer GI. The first interlayer insulation layer ILD1 may include a contact hole through which the first connection electrode CNE1 passes. The contact hole of the first interlayer insulation layer ILD1 may be connected to the contact hole of the gate insulation layer GI and the contact hole of the second interlayer insulation layer ILD2.

The capacitor electrode CPE may be arranged on the first interlayer insulation layer ILD1. The capacitor electrode CPE may overlap the gate electrode GE in the thickness direction. The capacitor electrode CPE and the gate electrode GE may form a capacitance.

The second interlayer insulation layer ILD2 may cover the capacitor electrode CPE and the first interlayer insulation layer ILD1. The second interlayer insulation layer ILD2 may include a contact hole through which the first connection electrode CNE1 passes. The contact hole of the second interlayer insulation layer ILD2 may be connected to the contact hole of the first interlayer insulation layer ILD1 and the contact hole of the gate insulation layer GI.

The first connection electrode CNE1 may be arranged on the second interlayer insulation layer ILD2. The first connection electrode CNE1 may electrically connect the drain electrode DE of the thin film transistor TFT to the second connection electrode CNE2. The first connection electrode CNE1 may be inserted into the contact holes formed in the second interlayer insulation layer ILD2, the first interlayer insulation layer ILD1, and the gate insulation layer GI and contact the drain electrode DE of the thin film transistor TFT.

The first passivation layer PAS1 may cover the first connection electrode CNE1 and the second interlayer insulation layer ILD2. The first passivation layer PAS1 may be formed on the thin film transistor TFT to protect the thin film transistor TFT. The first passivation layer PAS1 may include a contact hole through which the second connection electrode CNE2 passes. The first passivation layer PAS1 may include an organic material such as, for example, acrylic, benzocyclobutene (BCB), hexamethyldisiloxane (HMDSO), etc.

The second connection electrode CNE2 may be arranged on the first passivation layer PAS1. The second connection electrode CNE2 may electrically connect the first connection electrode CNE1 to a pixel electrode AE of the light-emitting element ED. The second connection electrode CNE2 may be inserted into a contact hole formed in the first passivation layer PAS1 and come into contact with the first connection electrode CNE1.

The second passivation layer PAS2 may be formed on the second connection electrode CNE2 and the first passivation layer PAS1 and cover the first passivation layer PAS1. The second passivation layer PAS2 may include a contact hole through which the pixel electrode AE of the light-emitting element ED passes. The second passivation layer PAS2 may include the same organic material as the first passivation layer PAS1, such as acrylic, benzocyclobutene (BCB), hexamethyldisiloxane (HMDSO), etc. The top surface of the second passivation layer PAS2 may be flat.

The light-emitting element layer EML may be arranged on the thin film transistor layer TFTL. The light-emitting element layer EML may include the light-emitting element ED and a pixel-defining film PDL. The light-emitting element ED may include the pixel electrode AE, the light-emitting layer EL, and the common electrode CE.

The pixel electrode AE may be arranged on the second passivation layer PAS2. The pixel electrode AE may be arranged to overlap any one of the openings OPE1, OPE2, and OPE3 of the pixel-defining film PDL. The pixel electrode AE may be electrically connected to the drain electrode DE of the thin film transistor TFT through the first and second connection electrodes CNE1 and CNE2.

The pixel-defining film PDL may be formed on the pixel electrode AE. The pixel-defining film PDL may be arranged on the second passivation layer PAS2 and a portion of the pixel electrode AE, including the plurality of openings OPE1, OPE2, and OPE3. The pixel-defining film PDL may include the first opening OPE1, the second opening OPE2, and the third opening OPE3, and each of the openings OPE1, OPE2, and OPE3 may expose a portion of the pixel electrode AE. As described herein, each of the openings OPE1, OPE2, and OPE3 of the pixel-defining film PDL may define the first to third light-emitting areas EA1, EA2, and EA3, and their areas or sizes may be different from each other. The pixel-defining film PDL may separate and insulate the pixel electrode AE of each of the plurality of light-emitting elements ED. The pixel-defining film PDL may include a light-absorbing material to prevent light reflection. For example, the pixel-defining film PDL may include a polyimide (PI)-based binder and a pigment mixed with red, green, and blue. The pixel-defining film PDL may include a mixture of a cardo-based binder resin, a lactam black pigment, and a blue pigment.

The light-emitting areas EA1, EA2, and EA3 may include a first light-emitting area EA1, a second light-emitting area EA2, and a third light-emitting area EA3 that emit light of different colors. The first to third light-emitting areas EA1, EA2, and EA3 may emit red, green, or blue light, respectively, and the color of the light emitted from each light-emitting area EA1, EA2, or EA3 may vary depending on the type of light-emitting element arranged in the light-emitting element layer EML described herein. In an embodiment, the first light-emitting area EA1 may emit first light of red, the second light-emitting area EA2 may emit second light of green, and the third light-emitting area EA3 may emit third light of blue. However, the disclosure is not limited thereto.

One first light-emitting area EA1, one second light-emitting area EA2, and one third light-emitting area EA3 arranged adjacent to one another may form one unit pixel UP in FIG. 5A. One unit pixel UP may express white gradations by including the light-emitting areas EA1, EA2, and EA3 that emit light of different colors. However, the disclosure is not limited thereto, and a combination of the light-emitting areas EA1, EA2, and EA3 constituting one unit pixel UP may be variously modified depending on the arrangement of the light-emitting areas EA1, EA2, and EA3 and the colors of light emitted by them.

The light-emitting layer EL may be arranged on the pixel electrode AE. The light-emitting layer EL may be formed corresponding to a light-emitting area defined by an opening of the pixel-defining film PDL. For example, the light-emitting layer EL may be an organic light-emitting layer formed of an organic material, but the disclosure is not limited thereto. For the light-emitting layer EL corresponding to an organic light-emitting layer, in case that the thin film transistor TFT applies a voltage to the pixel electrode AE of the light-emitting element ED and the common electrode CE of the light-emitting element ED receives a common voltage or cathode voltage, holes and electrons may move to the light-emitting layer EL through a hole transporting layer and an electron transporting layer, respectively, and the holes and electrons may be combined with each other in the light-emitting layer EL to emit light.

The common electrode CE may be arranged on the light-emitting layer EL. The common electrode CE may be formed such that the common electrode CE covers the top surface of the light-emitting layer EL. For example, the common electrode CE may be implemented as an electrode common to all pixels without being separated for each pixel. The common electrode CE may be arranged on the light-emitting layer EL in the first to third light-emitting areas EA1, EA2, and EA3, and may be arranged on the pixel-defining film PDL in an area excluding the first to third light-emitting areas EA1, EA2, and EA3. The common electrode CE may include, but is not limited to, a transparent conductive material which supports improved light extraction efficiency, and may also include a semi-permeable film including a metal.

The common electrode CE may receive a common voltage, a low-potential voltage, a second voltage, or an ELVSS. In case that the pixel electrode AE receives a voltage corresponding to the data voltage and the common electrode CE receives a low-potential voltage, a potential difference may be formed between the pixel electrode AE and the common electrode CE, causing the light-emitting layer EL to emit light.

The thin-film encapsulating layer TFE may be arranged on the common electrode CE and cover the plurality of light-emitting elements ED. The thin-film encapsulating layer TFE may include at least one inorganic film to prevent oxygen or moisture from penetrating into the light-emitting element layer EML. The thin-film encapsulating layer TFE may include at least one organic film to protect the light-emitting element layer EML from foreign substances such as dust.

The filler FL may be arranged on the thin-film encapsulating layer TFE. The optical functional layer OFL may be arranged on the filler FL, and the second substrate SUB2 may be arranged on the optical functional layer OFL. The filler FL, the optical functional layer OFL, and the second substrate SUB2 are the same as those described in FIG. 3A, and thus a redundant descriptions will be omitted.

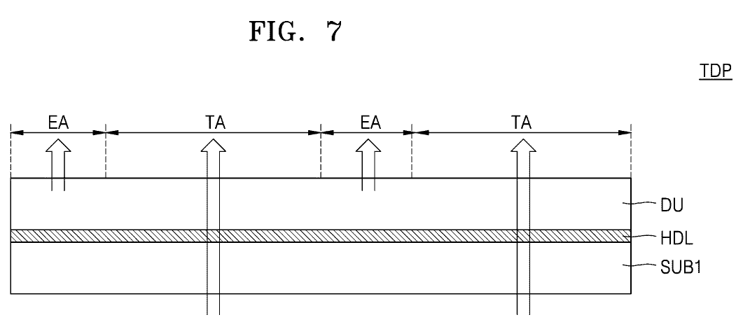

FIG. 7 is an explanatory view illustrating a portion of a display panel according to another embodiment of the disclosure. For convenience of description, only some of the components included in a transparent display panel TDP are illustrated in FIG. 7.

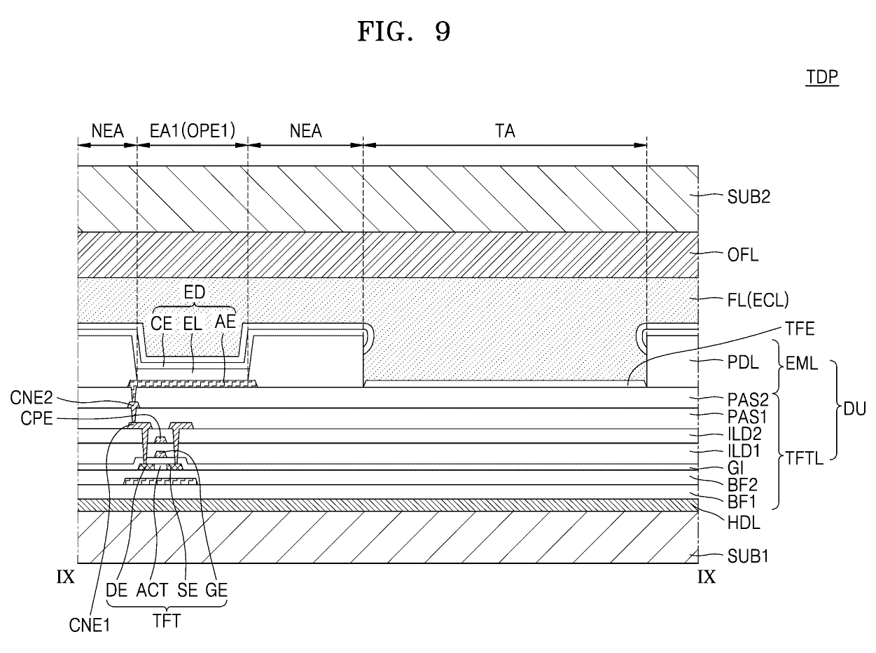

Referring to FIG. 7, the display panel may be the transparent display panel TDP. The transparent display panel TDP may include at least the first substrate SUB1 and the display layer DU provided on the first substrate SUB1. The display layer DU may include a light-emitting element ED of FIG. 9 that emits internal light. The light-emitting element ED in FIG. 9 may be provided corresponding to the light-emitting area EA. The transparent display panel TDP may transmit external light through a transparent window TA. Thus, the transparent display panel TDP may display an image through the light-emitting area EA while allowing objects arranged at the rear or external images to be visible via the transparent window TA.

In correspondence to the light-emitting area EA, various elements and wires may be provided in the display layer DU, such that the transmissivity of external light incident to the light-emitting area EA may be extremely low or hardly transmitted. However, as the display layer DU is not provided with various elements and wires in correspondence to the transparent window TA, the transmissivity of external light may be improved.

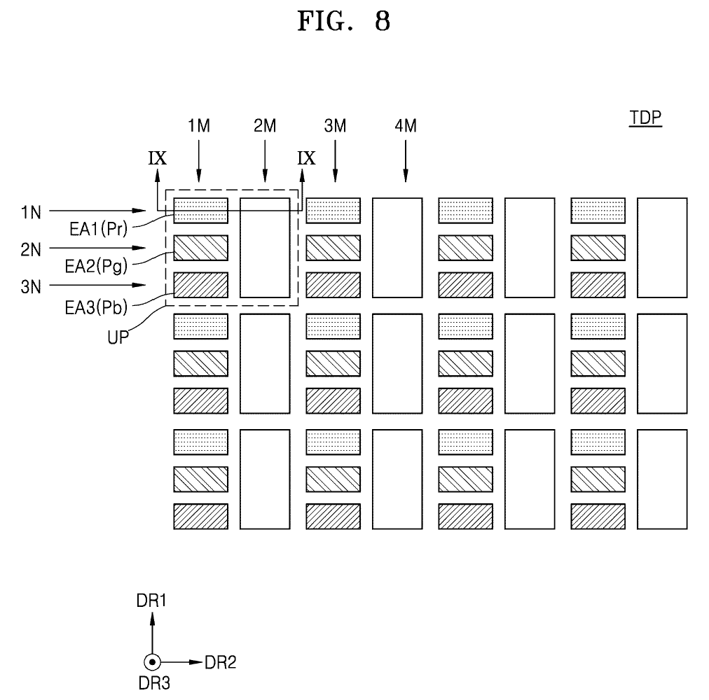

FIG. 8 is a plan view illustrating a pixel structure of the transparent display panel TDP.

Referring to FIG. 8, the unit pixel UP may include a plurality of sub-pixels Pr, Pg, and Pb. The light-emitting area EA may include the plurality of light-emitting areas EA1, EA2, and EA3 respectively corresponding to the plurality of sub-pixels Pr, Pg, and Pb. The transparent window TA may be positioned adjacent to the plurality of light-emitting areas EA1, EA2, and EA3. The transparent window TA may be commonly arranged in the plurality of light-emitting areas EA1, EA2, and EA3.

In the first column 1M, the red sub-pixel Pr, the green sub-pixel Pg, and blue sub-pixel Pb may be arranged alternately in the first direction DR1. In the second column 2M adjacent to the first column 1M, the plurality of transparent windows TA may be arranged continuously in the first direction DR1. Sub-pixels may be arranged in odd columns (or even columns), and transparent windows may be arranged in even columns (or odd columns).

In the first row 1N, the green sub-pixel Pg and the transparent window TA may be arranged alternately in the second direction DR2. In the second row 2N adjacent to the first row 1N, the red sub-pixel Pr and the transparent window TA may be arranged alternately in the second direction DR2. In the third row 3N adjacent to the second row 2N, the blue sub-pixel Pb and the transparent window TA may be arranged alternately in the second direction DR2. Such arrangement of the sub-pixels and the transparent window (TA) may be repeated up to a selected number of rows.

In an embodiment, the transparent window TA may be commonly arranged in the red sub-pixel Pr, the green sub-pixel Pg, and the blue sub-pixel Pb included in one unit pixel UP. The red sub-pixel Pr, the green sub-pixel Pg, and the blue sub-pixel Pb may have the same size, and the size of the transparent window TA may be greater than a sum of the sizes of the red sub-pixel Pr, the green sub-pixel Pg, or the blue sub-pixel Pb. The size of the transparent window TA is not limited thereto, and the size of the transparent window TA may change depending on the transmissivity of the display panel DP.

In an optional embodiment, the transparent window TA may be independently arranged in each of the red sub-pixel Pr, the green sub-pixel Pg, and the blue sub-pixel Pb included in one unit pixel UP.

FIG. 9 is a cross-sectional view cut along line IX-IX in FIG. 8.

Referring to FIG. 9, the transparent display panel TDP may include the first substrate SUB1, the heat-dissipating film HDL, the display layer DU, the thin-film encapsulating layer TFE, the filler FL, the optical functional layer OFL, and the second substrate SUB2. The display layer DU may include the thin film transistor layer TFTL and the light-emitting element layer EML. The transparent display panel TDP may have a configuration very similar to the display panel DP described in FIG. 6. Hereinbelow, a differences between the display panel DP of FIG. 6 and the transparent display panel TDP of FIG. 9 will be mainly described, and any description that overlaps FIG. 6 will be omitted.

The unit pixel UP in FIG. 8 of the transparent display panel TDP may include the light-emitting area EA1 in which the light-emitting element ED is arranged, the transparent window TA through which external light passes, and the non-light-emitting area NEA between the light-emitting area EA1 and the transparent window TA.

The first substrate SUB1 and the heat-dissipating film HDL are as described herein with reference to FIG. 6, and thus a redundant description will be omitted. Although FIG. 9 illustrates the embodiment of FIG. 3A, the disclosure is not limited thereto. The heat-dissipating film HDL may be arranged on the other surface of the optical functional layer OFL as described in FIG. 3B, or may be arranged on both a surface of the first substrate SUB1 and the other surface of the optical functional layer OFL as described in FIG. 3C. As the heat-dissipating film HDL is the same as described herein, a redundant description will be omitted.

The thin film transistor layer TFTL may include the first buffer layer BF1, the lower metal layer BML, the second buffer layer BF2, the thin film transistor TFT, the gate insulation layer GI, the first interlayer insulation layer ILD1, the capacitor electrode CPE, the second interlayer insulation layer ILD2, the first connection electrode CNE1, the first passivation layer PAS1, the second connection electrode CNE2, and the second passivation layer PAS2.

The thin film transistor TFT may include the semiconductor layer ACT, the source electrode SE, the drain electrode DE, and the gate electrode GE. The semiconductor layer ACT may include an oxide semiconductor.

The light-emitting element layer EML may be arranged on the thin film transistor layer TFTL. The light-emitting element layer EML may include the light-emitting element ED and the pixel-defining film PDL. The light-emitting element ED may include the pixel electrode AE, the light-emitting layer EL, and the common electrode CE.

The pixel electrode AE may be arranged on the second passivation layer PAS2.

The pixel-defining film PDL may be formed on the pixel electrode AE. The pixel-defining film PDL may include a transparent window opening corresponding to the transparent window TA in addition to a first opening OPE1 that exposes the pixel-defining film PDL.

The light-emitting layer EL may be arranged on the pixel electrode AE. The light-emitting layer EL may be formed corresponding to a light-emitting area defined by an opening of the pixel-defining film PDL.

The common electrode CE may be arranged on the light-emitting layer EL. The common electrode CE may be formed such that the common electrode CE covers the top surface of the light-emitting layer EL. For example, the common electrode CE may be implemented as an electrode common to all pixels without being separated for each pixel. The common electrode CE may be provided in an open structure corresponding to the transparent window TA. The common electrode CE may be removed at a location corresponding to the transparent window TA. The top surface of the display layer DU in the transparent window TA may be exposed, as the top surface is not covered by the pixel-defining film PDL and the common electrode CE.

The thin-film encapsulating layer TFE may be arranged on the common electrode CE and cover the plurality of light-emitting elements ED. The thin-film encapsulating layer TFE may directly cover the top surface of the display layer DU exposed through the transparent window TA. A part of the thin-film encapsulating layer TFE may be arranged on the second passivation layer PAS2. The thin-film encapsulating layer TFE may include inorganic and/or organic materials with high light transmittance to avoid blocking the transmission of external light through the transparent window TA.

In FIG. 9, the common electrode CE and the pixel-defining film PDL of the display layer DU corresponding to the transparent window TA are removed, but various embodiments may be implemented without being limited thereto. In an optional embodiment, at least one insulating film corresponding to the transparent window TA may be removed from the transparent display panel TDP, which may improve external light transmission. For example, a portion corresponding to the transparent window TA of at least one insulating film selected from the pixel-defining film PDL, the second passivation layer PAS2, the first passivation layer PAS1, the second interlayer insulating layer ILD2, the first interlayer insulating layer ILD1, the gate insulating layer GI, the second buffer layer BF2, or the first buffer layer BF1 may be removed.

According to an optional embodiment, as illustrated in FIGS. 3A-3C, the heat-dissipating film HDL may not be formed on the entire surface of the first substrate SUB1 or the optical functional layer OFL, but a portion of the heat-dissipating film HDL corresponding to the transparent window TA may be removed.

In conventional display devices, heat dissipation of a display panel is performed through a heat sink arranged on a rear surface of the first substrate SUB1. These heat sinks may usually include opaque graphite or metal. Thus, these conventional heat sinks may not be used in transparent display devices. For the transparent display device with the heat sink removed, momentary afterimages may be worsened and panel temperature may sharply increase in peak box tests. However, the transparent display panel TDP according to an embodiment may include the heat-dissipating film HDL. The heat-dissipating film HDL may include an insulating material with high thermal conductivity and high light transmissivity. Thus, the heat-dissipating film HDL may improve the heat dissipation characteristics of the transparent display device without affecting the transparency of the transparent display device.

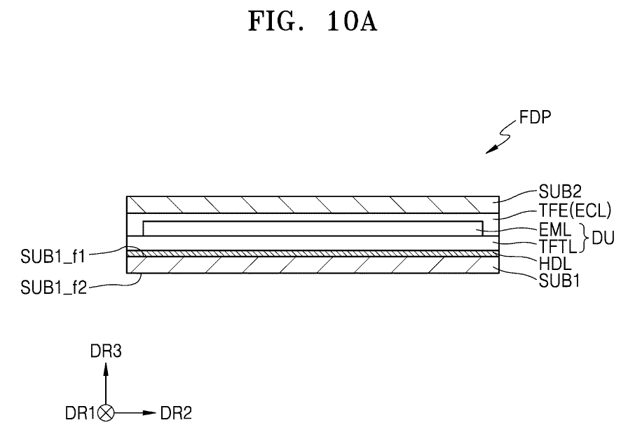

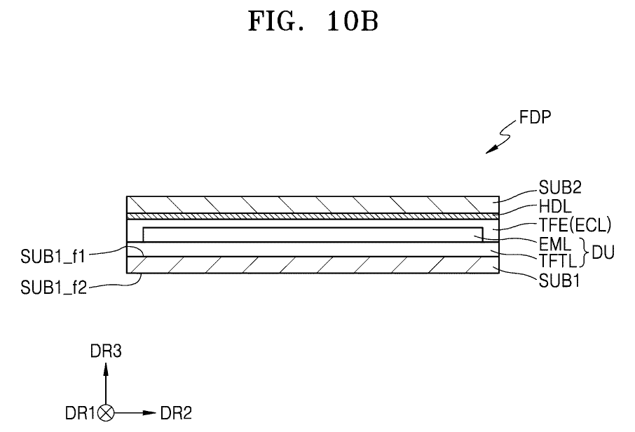

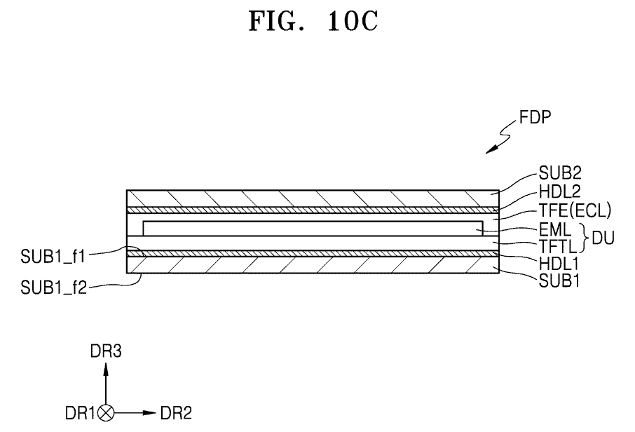

FIGS. 10A-10C are explanatory views illustrating a portion of a display panel according to another embodiment of the disclosure.

The display panel may be a flexible display panel FDP capable of bending, folding, rolling, etc. The flexible display panel FDP may include the first substrate SUB1, the display layer DU, the thin-film encapsulating layer TFE, and the second substrate SUB2 in the third direction DR3. The display layer DU may include the thin film transistor layer TFTL and the light-emitting element layer EML. The display layer DU, the thin film transistor layer TFTL, the light-emitting element layer EML, and the thin-film encapsulating layer TFE are the same as those described herein, and thus a redundant descriptions will be omitted. The thin-film encapsulating layer TFE may be referred to as an encapsulating layer ECL.

The first substrate SUB1 may be a flexible substrate capable of bending, folding, rolling, etc. For example, the first substrate SUB1 may include, but is not limited to, a polymer resin such as polyimide (PI).

The second substrate SUB2 may be a very thin substrate and may be a cover window. For example, the second substrate SUB2 may be, but is not limited to, ultra-thin glass.

Referring to FIG. 10A, the first substrate SUB1 may include a surface SUB1_f1 and the other surface SUB1_f2 opposite thereto. The heat-dissipating film HDL may be arranged on the surface SUB1-f1 of the first substrate. Referring to FIG. 10B, the heat-dissipating film HDL may be arranged between the thin-film encapsulating layer TFE and the second substrate SUB2. The heat-dissipating film HDL may be formed directly on the second substrate SUB2, but the disclosure is not limited thereto. Referring to FIG. 10C, the heat-dissipating film (HDL) may include the first heat-dissipating film HDL1 and the second heat-dissipating film HDL2, in which the first heat-dissipating film HDL1 may be arranged between the first substrate SUB1 and the display layer DU, and the second heat-dissipating film HDL2 may be arranged between the thin-film encapsulating layer TFE and the second substrate SUB2. As the heat-dissipating film HDL is the same as described herein, a redundant description will be omitted.

Herein, the “encapsulating layer ECL” may collectively refer to a component that is arranged on the display layer DU to protect a display element. The “encapsulating layer ECL” may include at least the filler FL in the embodiments of FIGS. 1-9. For example, the encapsulating layer ECL may refer to the filler FL, a combination of the thin-film encapsulating layer TFE and the filler FL, or a combination of the thin-film encapsulating layer TFE, the filler FL, and the sealant SAL. The disclosure is not limited thereto, and the term “encapsulating layer ECL” in the embodiments of FIGS. 10A-10C may also refer to the thin-film encapsulating layer TFE.

Herein, the “second substrate SUB2” may collectively refer to a component facing the first substrate SUB1. The term “second substrate SUB2” may mean an encapsulating substrate in the embodiments of FIGS. 1-9. The disclosure is not limited thereto, and the term “second substrate SUB2” in the embodiments of FIGS. 10A-0C may also refer to a cover window.

The display device DD according to an embodiment may be applied to various electronic devices 1000. The electronic device according to an embodiment may include the display device DD described herein, and may further include a module or device having additional functions in addition to the display device DD.

FIG. 11 is a block diagram of an electronic device 1000 according to an embodiment.

Referring to FIG. 11, the electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The controller may output various control signals supportive of driving the display module 1100. For example, the controller may apply various signals to the pixel circuit included in the thin film transistor layer TFTL. The controller may transmit a scan control signal to the scan driver SDV, and causes the scan driver SDV to output scan signals to pixel circuits in response to the scan control signal. The controller may transmit a control signal to the data driver of the display driving unit DIC, and the data driver may convert image data into an analog voltage (e.g., a data voltage) in response to the control signal and output the data voltage to the pixel circuits.

The memory 1300 may store data information supportive of the operation of the processor 1200 or the display module 1100. In an example in which the processor 1200 executes an application stored in the memory 1300, an image data signal and/or an input control signal may be transmitted to the display module 1100, and the display module 1100 may process the received signal and output the image information through a display screen.

The power module 1400 may include a power supply module, such as a power adapter, a battery device, etc., and a power conversion module that converts power supplied by the power supply module to generate power for the operation of the electronic device 1000. For example, the power module 1400 may supply power to the controller, enabling the controller to operate.

At least one of the components of the electronic device 1000 may be included in the display device according to the above-described embodiments. Some of the individual modules functionally included in a module may be included in the display device and others may be provided separately from the display device. For example, the display device may include the display module 1100, and the processor 1200, the memory 1300, and the power module 1400 may be provided in the form of other devices in the electronic device 1000 other than the display device.

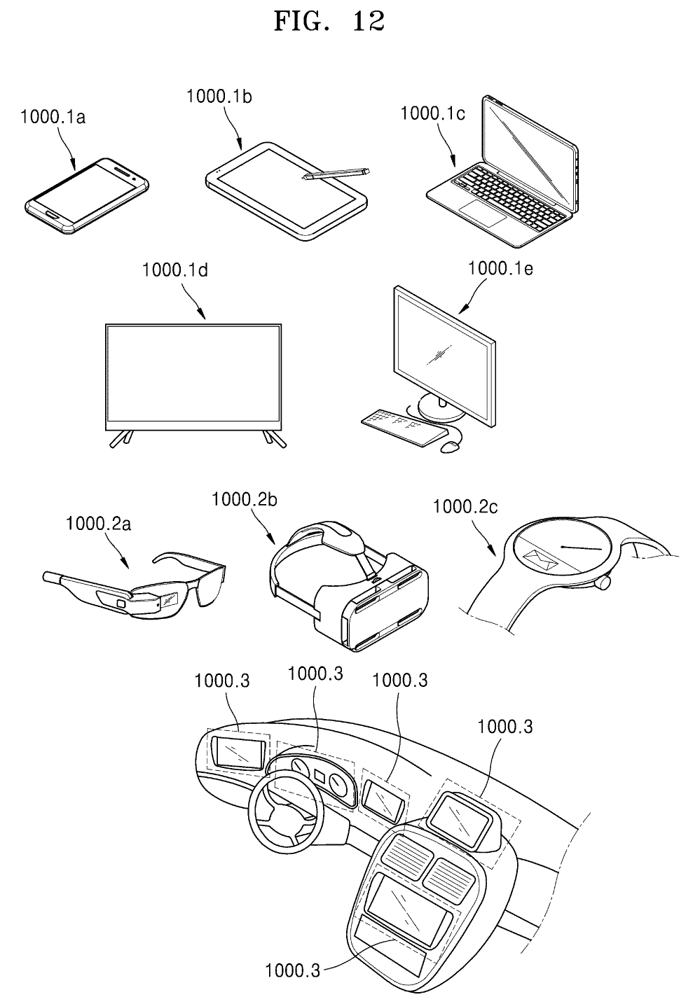

FIG. 12 show schematic diagrams of an electronic device according to various embodiments.

Referring to FIG. 12, various electronic devices to which the display device according to embodiments is applied may include not only image display electronic devices such as a smartphone 1000_1a, a tablet PC 1000_1b, a laptop computer 1000_1c, a TV 1000_1d, a desk monitor 1000_1e, etc., but also wearable electronic devices including display modules such as smart glasses 1000_2a, a head mounted display 1000_2b, a smart watch 1000_2c, etc., and vehicle electronic devices 1000_3 including display modules such as an instrument panel, a center fascia, a center information display (CID) arranged on a dashboard, a room mirror display, etc., of vehicles.

The display device and the electronic device including the display device according to embodiments of the disclosure may have improved heat dissipation performance. However, the scope of the disclosure is not limited by these effects.

While some embodiments have been described, it will be readily apparent to those of skill in the art that various modifications may be made therein without departing from the spirit and scope of the disclosure. Unless otherwise stated, the description of characteristics or aspects in each embodiment should generally be considered to be applicable to other similar characteristics or aspects of other embodiments. Accordingly, as will be apparent to those of ordinary skill in the art, characteristics or components described in connection with a particular embodiment may be combined with characteristics or components described in connection with other embodiments. Therefore, the foregoing description should not be construed as limited to the specific embodiments disclosed herein, but should be understood to be intended for combination with or application to other embodiments. Accordingly, the true technical scope of the disclosure should be defined by the technical spirit of the appended claims.

What is claimed is:

1. A display device comprising:
a first substrate comprising one surface and another surface opposite to the one surface;
a display layer positioned on the one surface of the first substrate and which displays an image;
an encapsulating layer covering the display layer;
a second substrate positioned on the encapsulating layer; and
at least one heat-dissipating film arranged between the first substrate and the second substrate and comprising aluminum nitride (AlN).

2. The display device of claim 1, wherein the at least one heat-dissipating film is positioned between the one surface of the first substrate and the display layer.

3. The display device of claim 2, wherein the at least one heat-dissipating film is formed directly on the one surface of the first substrate.

4. The display device of claim 1, wherein:
the encapsulating layer comprises a thin-film encapsulating layer, and
the at least one heat-dissipating film is positioned between the thin-film encapsulating layer and the second substrate.

5. The display device of claim 1, wherein:
the encapsulating layer comprises at least a filler, and
the at least one heat-dissipating film is positioned between the filler and the second substrate.

6. The display device of claim 1, wherein:
the encapsulating layer comprises at least a filler,
the display device further comprises an optical functional layer which is positioned on the filler, scatters external light, and comprises one surface and another surface opposite to the one surface and facing the encapsulating layer, and
the at least one heat-dissipating film is formed directly on the other surface of the optical functional layer.

7. The display device of claim 1, wherein:
the at least one heat-dissipating film comprises a first heat-dissipating film and a second heat-dissipating film,
the first heat-dissipating film is positioned between the one surface of the first substrate and the display layer, and
the second heat-dissipating film is positioned between the encapsulating layer and the second substrate.

8. The display device of claim 7, wherein the first heat-dissipating film and the second heat-dissipating film have a same thickness.

9. The display device of claim 7, wherein the first heat-dissipating film and the second heat-dissipating film have different respective thicknesses.

10. The display device of claim 1, wherein:
the display device further comprises an optical functional layer which is positioned on the encapsulating layer, scatters external light, and comprises one surface and another surface opposite to the one surface and facing the encapsulating layer, and
the at least one heat-dissipating film comprises a first heat-dissipating film and a second heat-dissipating film,
the first heat-dissipating film is formed directly on the one surface of the first substrate, and
the second heat-dissipating film is formed directly on the other surface of the optical functional layer.

11. The display device of claim 1, wherein a thickness of the at least one heat-dissipating film is more than 0 micrometer, but not more than 1 micrometer.

12. The display device of claim 1, wherein a thermal conductivity of the at least one heat-dissipating film in a planar direction is at least 55 W/mK, but not more than 200 W/mK.

13. The display device of claim 1, wherein a light transmissivity of the at least one heat-dissipating film is at least 70%, but not more than 95% at a wavelength of 400 nanometers to 800 nanometers.

14. The display device of claim 1, wherein:
the display layer comprises at least one unit pixel, and
the at least one unit pixel comprises a plurality of light-emitting areas which emit light and at least one transparent window which transmits external light.

15. The display device of claim 14, wherein the at least one transparent window is arranged in common across the plurality of light-emitting areas.

16. The display device of claim 14, wherein at least one insulating layer of the display layer corresponding to the at least one transparent window is removed.

17. An electronic device comprising:
a first substrate comprising one surface and another surface opposite to the one surface;
a display layer positioned on the one surface of the first substrate and comprising at least one unit pixel comprising a plurality of sub-pixels;
an encapsulating layer covering the display layer;
a second substrate positioned on the encapsulating layer;
a controller which applies a signal to a pixel circuits respectively comprised in the plurality of sub-pixels;
a power module which applies power to the controller; and
at least one heat-dissipating film arranged between the first substrate and the second substrate and comprising aluminum nitride (AlN), wherein the at least one heat-dissipating film has a thickness being more than 0 micrometer, but not more than 1 micrometer.

18. The electronic device of claim 17, wherein the at least one heat-dissipating film is formed directly on the one surface of the first substrate.

19. The electronic device of claim 17, wherein the at least one heat-dissipating film is formed between the encapsulating layer and the second substrate.

20. The electronic device of claim 17, further comprising an optical functional layer which is positioned on the encapsulating layer, scatters external light, and comprises one surface and another surface opposite to the one surface and facing the encapsulating layer,
wherein:
the at least one heat-dissipating film comprises a first heat-dissipating film and a second heat-dissipating film,
the first heat-dissipating film is formed directly on the one surface of the first substrate, and
the second heat-dissipating film is formed directly on the other surface of the optical functional layer.
